(19) United States
(12) Patent Application Publication
(10) Pub. No.: US 2024/0038739 A1
(43) Pub. Date: Feb. 1, 2024

(54) SEMICONDUCTOR PACKAGE

(71) Applicant: SAMSUNG ELECTRONICS CO., LTD., Suwon-si (KR)

(72) Inventor: Jongwon LEE, Suwon-si (KR)

(73) Assignee: SAMSUNG ELECTRONICS CO., LTD., Suwon-si (KR)

(21) Appl. No.: 18/226,534

(22) Filed: Jul. 26, 2023

(30) Foreign Application Priority Data
Jul. 28, 2022 (KR) 10-2022-0093965

(51) Int. Cl. H01L 25/10; H10B 80/00; H01L 23/31; H01L 23/498; H01L 23/00

(52) U.S. Cl. CPC H01L 25/105; H10B 80/00; H01L 23/3107; H01L 23/49822; H01L 23/49838; H01L 24/08; H01L 24/09; H01L 24/16; H01L 24/32; H01L 24/73; H01L 2225/1035; H01L 2225/1041; H01L 2225/1058; H01L 2224/08148; H01L 2224/08225; H01L 2224/09051; H01L 2224/16148; H01L 2224/16227; H01L 2224/16238; H01L 2224/32145; H01L 2224/32225; H01L 2224/73204; H01L 2924/1431

(57) ABSTRACT

A semiconductor package includes a first redistribution structure having a first redistribution layer; a first semiconductor chip on the first redistribution structure, and having first lower pads, first upper pads, and first through-electrodes; a second semiconductor chip on the first semiconductor chip, and having second lower pads, second upper pads, and second through-electrodes; a vertical connection conductor on the first redistribution structure, and connected to the first redistribution layer; a molded portion on the first redistribution structure, and surrounding the first second semiconductor chips; a second redistribution structure on the second semiconductor chip and the vertical connection conductor, the second redistribution structure having a second redistribution layer connected to the second upper pads and the vertical connection conductor; and a third semiconductor chip on the second redistribution structure, and having contact pads connected to the second redistribution layer.

### CROSS-REFERENCE TO RELATED APPLICATION

This application is based on and claims priority under 35 U.S.C. § 119 to Korean Patent Application No. 10-2022-0093965, filed on Jul. 28, 2022, with the Korean Intellectual Property Office, the disclosure of which is incorporated by reference herein in its entirety.

### BACKGROUND

### 1. Field

The disclosure relates to a semiconductor package.

### 2. Description of Related Art

Recently, in the electronic products market, demand for portable devices has been rapidly increasing, and accordingly, miniaturization and weight reduction of electronic components mounted on such products are continuously required. For the miniaturization and weight reduction of electronic components, it is also required to improve a degree of integration of semiconductor devices used in electronic components.

A semiconductor package mounted on an electronic device is required to have high performance and high capacitance along with miniaturization. In order to implement the same, research and development of a three-dimensional semiconductor package in which semiconductor chips including through silicon vias (TSV) are vertically stacked are being conducted.

### SUMMARY

An aspect of the disclosure is to provide a semiconductor package having improved performance by shortening an interface path.

In accordance with an aspect of the disclosure, a semiconductor package includes a first redistribution structure including a first redistribution layer; a first semiconductor chip on the first redistribution structure, the first semiconductor chip including first lower pads, first upper pads, and first through-electrodes electrically connecting the first lower pads to the first upper pads, wherein the first lower pads are electrically connected to the first redistribution layer; a second semiconductor chip on the first semiconductor chip, the second semiconductor chip including second lower pads, second upper pads, and second through-electrodes electrically connecting the second lower pads to the second upper pads, wherein the second lower pads are electrically connected to the first upper pads; a vertical connection conductor around the first semiconductor chip and the second semiconductor chip on the first redistribution structure, wherein the vertical connection conductor is electrically connected to the first redistribution layer; a molded portion on the first redistribution structure, wherein the molded portion surrounds the first semiconductor chip and the second semiconductor chip; a second redistribution structure on the second semiconductor chip and the vertical connection conductor, the second redistribution structure including a second redistribution layer connected to the second upper pads and to the vertical connection conductor; and a third semiconductor chip on the second redistribution structure, the third semiconductor chip including contact pads electrically connected to the second redistribution layer.

In accordance with an aspect of the disclosure, a semiconductor package includes a first redistribution structure including a first redistribution layer; a first logic chip on the first redistribution structure, the first logic chip including first lower pads, first upper pads, and first through-electrodes electrically connecting the first lower pads to the first upper pads, wherein the first lower pads are electrically connected to the first redistribution layer, and wherein the first logic chip includes a first processor core portion and a logic portion; a second logic chip on the first logic chip, the second logic chip including second lower pads, second upper pads, and second through-electrodes electrically connecting the second lower pads to the second upper pads, wherein the second lower pads are electrically connected to the first upper pads, and wherein the second logic chip includes a second processor core portion and a memory interface portion; conductive posts around the first logic chip and the second logic chip on the first redistribution structure, wherein the conductive posts are electrically connected to the first redistribution layer; a molded portion on the first redistribution structure, wherein the molded portion surrounds the first logic chip, the second logic chip, and the conductive posts; a second redistribution structure on an upper surface of the second logic chip and an upper surface of the molded portion, the second redistribution structure including a second redistribution layer connected to the second upper pads and to the conductive posts; and a memory chip on the second redistribution structure, the memory chip including contact pads electrically connected to the second redistribution layer.

In accordance with an aspect of the disclosure, a semiconductor package includes a first redistribution structure including a first redistribution layer; a frame on the first redistribution structure, the frame including an interconnection structure connected to the first redistribution layer, wherein the frame includes a cavity passing through an upper surface of the frame and a lower surface of the frame; a first logic chip on the first redistribution structure within the cavity of the frame, the first logic chip including first lower pads, first upper pads, and first through-electrodes electrically connecting the first lower pads to the first upper pads, wherein the first lower pads are electrically connected to the first redistribution layer, and wherein the first logic chip includes a first processor core portion and a logic portion; a second logic chip on the first logic chip within the cavity, the second logic chip including second lower pads, second upper pads, and second through-electrodes electrically connecting the second lower pads to the second upper pads, wherein the second lower pads are electrically connected to the first upper pads, and wherein the second logic chip includes a second processor core portion and a memory interface portion; a molded portion surrounding the first logic chip and the second logic chip within the cavity; a second redistribution structure on an upper surface of the second logic chip and an upper surface of the frame, the second redistribution structure including a second redistribution layer connected to the second upper pads and to the interconnection structure; and a memory chip on the second redistribution structure, the memory chip including contact pads electrically connected to the second redistribution layer.

### BRIEF DESCRIPTION OF DRAWINGS

The above and other aspects, features, and advantages of the disclosure will be more clearly understood from the following detailed description taken in conjunction with the accompanying drawings, in which:

FIG. 1 is a side cross-sectional view of a semiconductor package according to an example embodiment;

FIGS. 2A and 2B are plan cross-sectional views of the semiconductor package illustrated in FIG. 1 taken through I1-I1′ and I2-I2′, respectively;

FIG. 3 is a side cross-sectional view illustrating a chip stack (first and second semiconductor chips) introduced into the semiconductor package illustrated in FIG. 1;

FIGS. 4A and 4B are schematic plan views illustrating a floor plan of each of the first semiconductor chip and the second semiconductor chip illustrated in FIG. 3, respectively;

FIG. 5 is a side cross-sectional view of a semiconductor package according to an example embodiment;

FIG. 6 is a side cross-sectional view illustrating a chip stack (first and second semiconductor chips) introduced into the semiconductor package illustrated in FIG. 5;

FIGS. 7 to 10 are cross-sectional side views of semiconductor packages according to various example embodiments;

FIGS. 11A to 11E are cross-sectional views for each main process for illustrating a method of manufacturing the semiconductor package illustrated in FIG. 1; and

FIGS. 12A to 12E are cross-sectional views for each main process for illustrating a method of manufacturing the semiconductor package illustrated in FIG. 8.

### DETAILED DESCRIPTION

Hereinafter, preferred embodiments of the disclosure will be described with reference to the accompanying drawings. Hereinafter, terms such as ‘an upper side, ‘an upper portion’, ‘an upper surface’, a lower side, a lower portion, a lower surface, and the like, may be understood as referring to the drawings, except where otherwise indicated by reference numerals.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. Like numerals refer to like elements throughout.

Spatially relative terms, such as “over,” “above,” “on,” “upper,” “below,” “under,” “beneath,” “lower,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

For the sake of brevity, conventional elements to semiconductor devices may or may not be described in detail herein for brevity purposes.

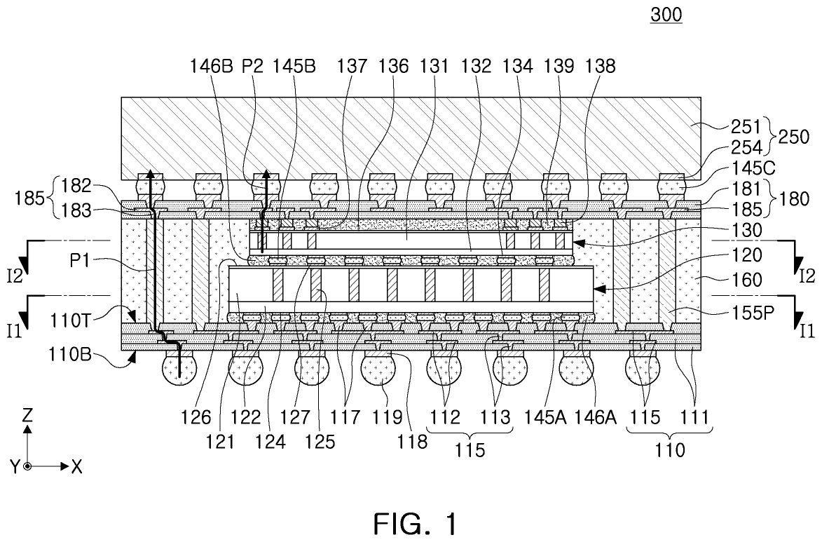

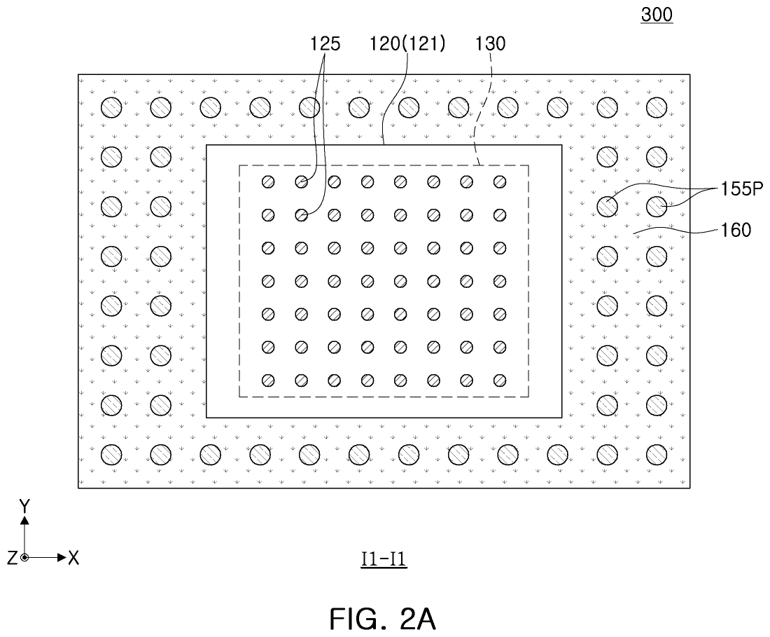

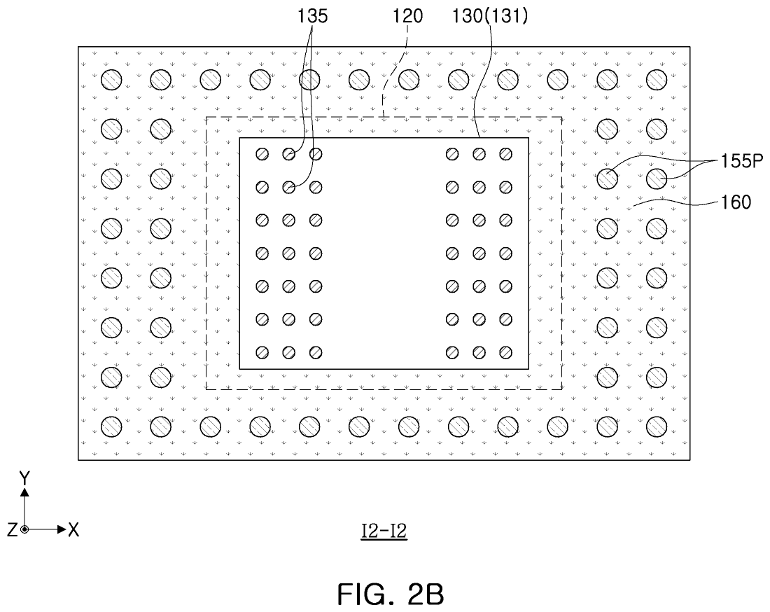

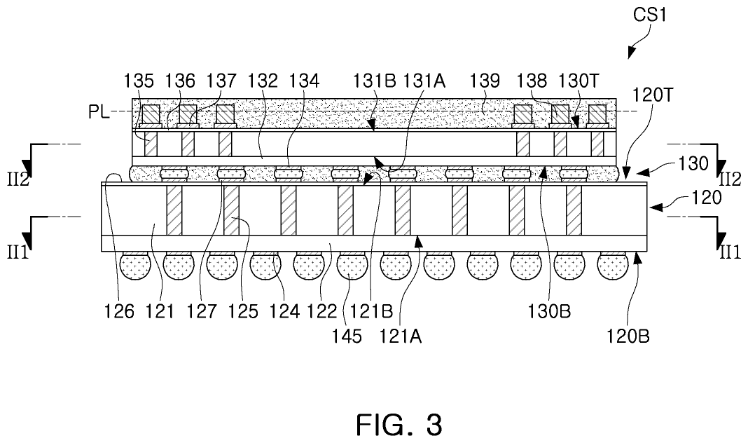

FIG. 1 is a side cross-sectional view of a semiconductor package according to an example embodiment of the disclosure, FIGS. 2A and 2B are plan cross-sectional views taken by cutting I1-I1 and I2-I2 of the semiconductor package illustrated in FIG. 1, respectively, and FIG. 3 illustrates a chip stack CS1 employed in the semiconductor package illustrated in FIG. 1.

Referring to FIGS. 1 and 2A and 2B, a semiconductor package 300 according to an embodiment includes: a first redistribution structure 110 having a first redistribution layer 115, a first semiconductor chip 120 stacked on the first redistribution structure 110, a second semiconductor chip 130 disposed on the first semiconductor chip 120, conductive posts 155P disposed around the stacked first and second semiconductor chips 120 and 130 on the first redistribution structure 110, a molded portion 160 disposed on the first redistribution structure 110, and surrounding the stacked first and second semiconductor chips 120 and 130 and the conductive posts 155P, and a second redistribution structure 180 disposed on the molded portion 160 and the second semiconductor chip 130. The semiconductor package 300 may further include a third semiconductor chip 250 disposed on the second redistribution structure 180.

In this arrangement, the second semiconductor chip 130 may not only be configured to transmit signals to and from the first semiconductor chip 120, but also transmit signals to and from the third semiconductor chip 250 by way of the second redistribution layer 185. In the arrangement according to an embodiment, when a specific function for communicating with the third semiconductor chip among the functions of the first semiconductor chip is configured to be included in the second semiconductor chip, an effect capable of shortening an interface path for the specific function is provided. A detailed description thereof will be provided later.

Referring to FIG. 3 together with FIG. 1, a chip stack CS1 includes a first semiconductor chip 120 disposed on the first redistribution structure 110, and a second semiconductor chip 120 disposed on the first semiconductor chip 120.

The first semiconductor chip 120 includes first lower pads 124 electrically connected to the first redistribution layer 115, first upper pads 127, and first through-electrodes 125 electrically connecting the first lower pads 124 to the first upper pads 127. In detail, referring to FIGS. 1 and 3, the first semiconductor chip 120 may include a first semiconductor substrate 121 having a first active surface 121A and a first inactive surface 121B positioned opposite to each other, a first circuit layer 122 disposed on the first active surface 121A, and a first back side insulating layer 126 disposed on the inactive surface 121B of the first semiconductor substrate 121. For example, the first semiconductor substrate 121 may include silicon (Si), germanium (Ge), or gallium arsenide (GaAs). As used herein, the “active surface” includes an active region doped with impurities, and a plurality of active/passive devices (e.g., transistors) may be formed in the active region. The circuit layer 112 may include an interconnection circuit connected to the devices.

The first lower pads 124 may be disposed on the first circuit layer 122 and may be connected to an interconnection circuit of the first circuit layer 122. The first through-electrodes 125 may penetrate through the first semiconductor substrate 121 and may be electrically connected to the first lower pads 124 through the interconnection circuit of the first circuit layer 122. The first upper pads 127 may be disposed on the first back side insulating layer 126, and may be respectively connected to the first through-electrodes 125. In some example embodiments, the first back side insulating layer 126 may include an additional interconnection circuit.

In an embodiment, a connection between the first semiconductor chip 120 and the first redistribution structure 110 may be implemented by microbumps having a fine pitch. Specifically, as illustrated in FIG. 1, the first lower pads 124 of the first semiconductor chip 120 may be respectively connected to the first redistribution layer 115, in particular, by first conductive bumps 145A. Additionally, a first non-conductive film 146A may be disposed between the first semiconductor chip 120 and the first redistribution structure 110 to surround the first conductive bumps 145A.

The second semiconductor chip 130 may be stacked on the first semiconductor chip 120, and include second lower pads 134, second upper pads 137, and second through-electrodes 135 electrically connecting the second lower pads 134 to the second upper pads 137. The second lower pads 134 may be electrically connected to the first upper pads 127. In detail, referring to FIGS. 1 and 3, similarly to the first semiconductor chip 120, the second semiconductor chip 130 may include a second semiconductor substrate 131 having a second active surface 131A and a second inactive surface 131B located opposite to each other, a second circuit layer 132 disposed on the second active surface 131A, and a second back side insulating layer 136 disposed on the non-active surface 131B of the second semiconductor substrate 131.

The second lower pads 134 may be disposed on a second circuit layer 132 and may be connected to an interconnection circuit of the second circuit layer 132. The second through-electrodes 135 may penetrate through the second semiconductor substrate 131 and may be electrically connected to the second lower pads 134 by way of the interconnection circuit of the second circuit layer 132. The second upper pads 137 may be disposed on the first back side insulating layer 136, and may be respectively connected to the first through-electrodes 135. In some example embodiments, the second back side insulating layer 136 may include an additional interconnection circuit.

In an embodiment, connection (or stack) between the first semiconductor chip 120 and the second semiconductor chip 130 may be implemented by microbumps. Specifically, as illustrated in FIGS. 1 and 3, the second lower pads 134 of the second semiconductor chip 130 may be respectively connected to the first upper pads 127 of the first semiconductor chip 120 by the second conductive bumps 145B to ensure signal transmission between the first and second semiconductor chips 120 and 130.

Additionally, a second non-conductive film 146B may be disposed between the first semiconductor chip 120 and the second semiconductor chip 130 to surround the second conductive bumps 145A to ensure a solid connection.

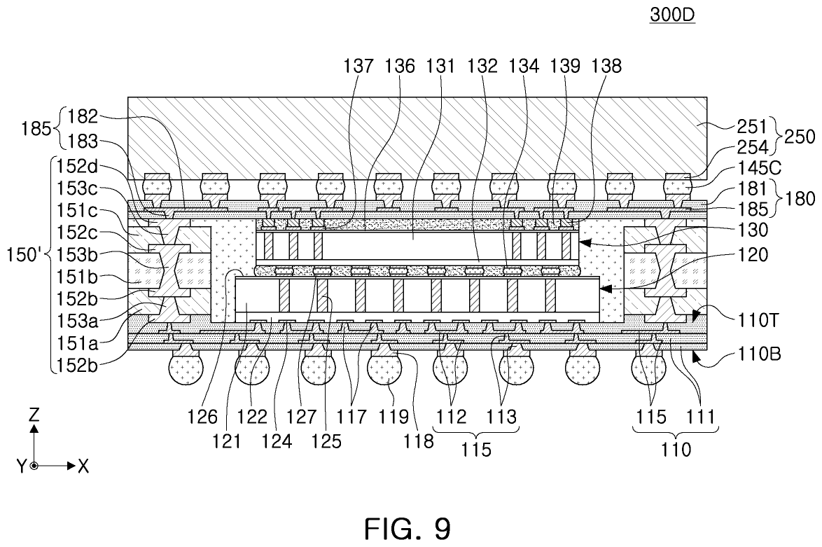

Such a stacking process may be performed in a manner (also referred to as a “chip-on-wafer process”) in which single second semiconductor chips are respectively mounted on a wafer in which a plurality of first semiconductor chips 120 are implemented. In an example embodiment, the stacking process of the first semiconductor chip 120 and the second semiconductor chip 130 may also be performed by metal-metal junction and dielectric-dielectric junction (refer to FIG. 9).

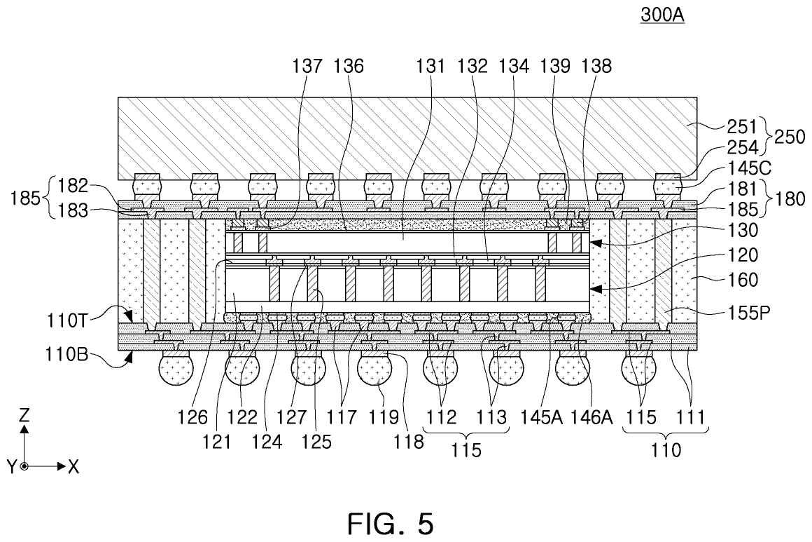

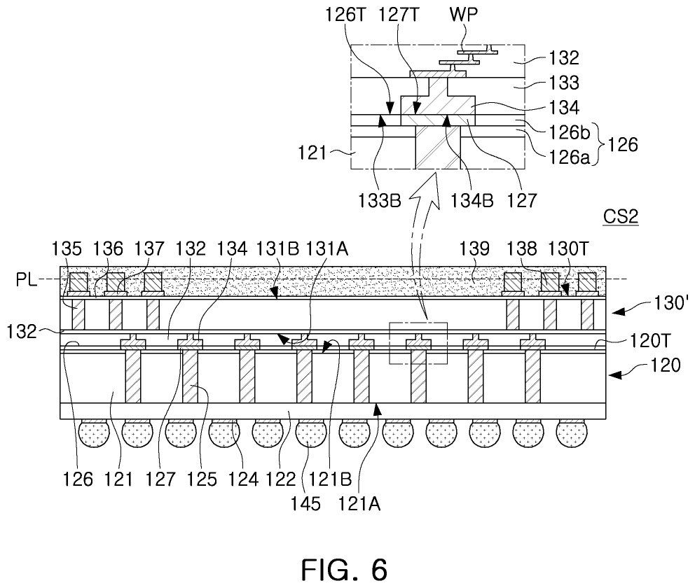

The second semiconductor chip 130 may have a different area than an area of the first semiconductor chip 120. As illustrated in FIG. 1, the first semiconductor chip 120 may have a larger area than that of the second semiconductor chip 130. In some example embodiments, the first semiconductor chip 120 and the second semiconductor chip 130 may have the same area (see FIGS. 5 and 6).

The molding unit 160 may be disposed between the first and second redistribution structures 110 and 180, and may be configured to surround the first and second semiconductor chips 120 and 130 and the conductive posts 155P. The molding unit 160 may have a substantially flat upper surface with an upper end of the conductive posts 155P. For example, the molding unit 160 may include an insulating resin such as epoxy mold compound (EMC).

The second redistribution structure 180 may be disposed on the upper surface of the second semiconductor chip 130 and the upper surface of the molding unit 180, and may have a second redistribution layer 185 connected to the second upper pads 137 and the conductive posts 155P.

The upper pads 137 of the second semiconductor chip 130 employed in this embodiment may be connected to the second redistribution layer 185 through contact posts 138. Specifically, the second semiconductor chip 130 may include contact posts 138 respectively disposed on the second upper pads 137 and having a predetermined height, and a molding layer 139 disposed on an upper surface of the second semiconductor chip 130 and surrounding the contact posts 138.

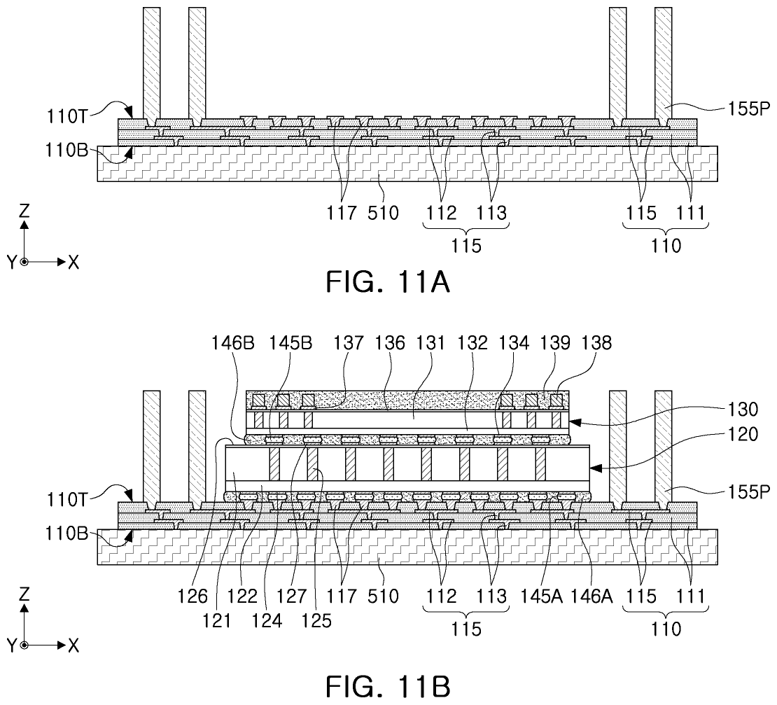

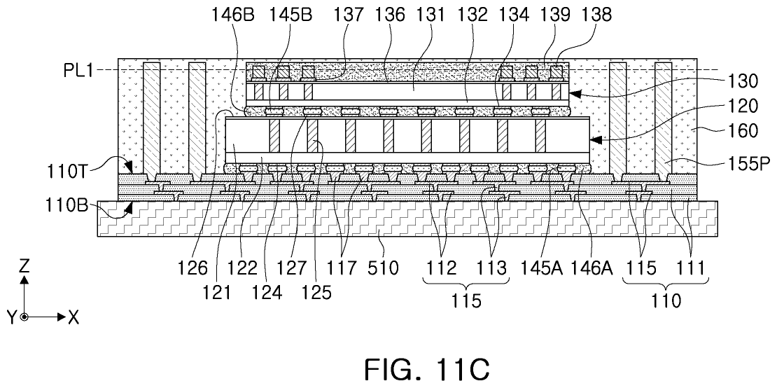

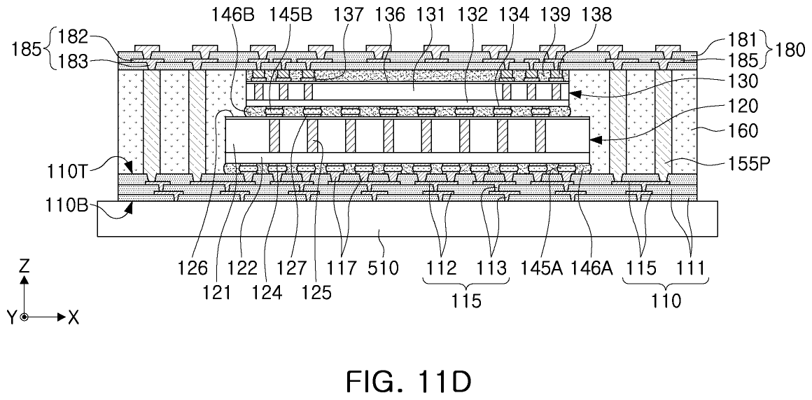

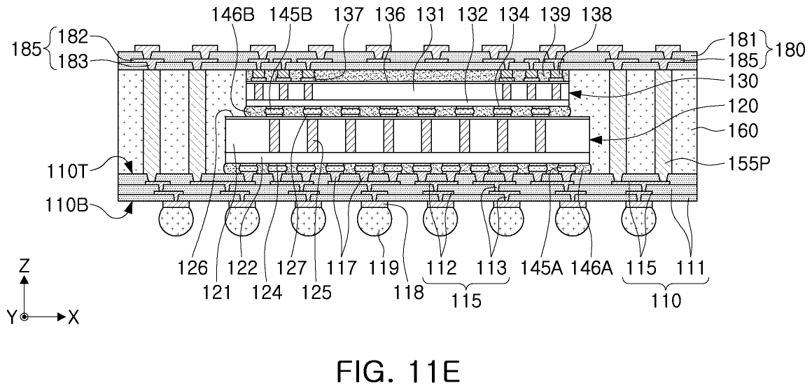

As illustrated in FIG. 3, a molding layer 139 may be configured to cover the contact posts 138 formed to have a predetermined height at a chip level, but as illustrated in FIG. 1, the molding layer 139 may be planarized along a line marked “PL” to have an upper surface that is flat and coplanar with an upper surface of the contact posts 138 at a package level. This planarization process may be performed together with the planarization process of the molding part 160 (please refer to FIG. 11C), so that an upper surface of the molding unit 160 may form a flat coplanar surface with the upper surface of the molding layer 139.

As described above, since the molded portion 160 and the molding layer 139 have planarized upper surfaces, the second redistribution structure 180 can be easily formed thereon.

The first redistribution structure 110 may include a plurality of insulating films 111, and first redistribution layers 115 respectively formed on the plurality of first insulating films 111, and may be provided in a form of a substrate. Similarly thereto, the second redistribution structure 180 also includes a plurality of second insulating films 181 and a second redistribution layer 185 respectively formed on the plurality of second insulating films 181. Although examples of the first and second redistribution structures 110 and 180 employed in this embodiment are shown as including two redistribution layers, in another example embodiment, the first and second redistribution structures 110 and 180 may be implemented to include one or two or more insulating films and redistribution layers. For example, at least one of the first and second insulating layers 111 and 181 may use a photosensitive insulating material such as a photosensitive insulating (PID) resin. When the insulating layers 111 and 181 are formed of a photosensitive insulating resin, the first and second redistribution layers 115 and 185 may be formed in a fine pattern using a photolithography process. In some example embodiments, at least one of the first and second insulating layers 111 and 181 may include a thermosetting resin such as an epoxy resin, or a thermoplastic resin such as polyimide.

The first redistribution layer 115 may include a first redistribution pattern 112 disposed on a first insulating film 111, and a first redistribution via 113 connected to the first redistribution pattern 112 and penetrating through the first insulating film 111. Similarly thereto, the second redistribution layer 185 may include a second redistribution pattern 182 disposed on a second insulating film 181, and a second redistribution via 183 connected to the second redistribution pattern 182 and penetrating through the second insulating film 181. At the same level (e.g., the same insulating layer), the first and second redistribution vias 113 and 183 may be formed together with the first and second redistribution patterns 112 and 182 using the same plating process, respectively. For example, at least one of the first and second redistribution layers 115 and 185 may include a conductive material such as copper (Cu), aluminum (Al), silver (Ag), tin (Sn), gold (Au), nickel (Ni), lead (Pb), titanium (Ti), or alloys thereof. In some example embodiments, the first and second redistribution layers 115 and 185 may include an additional pattern (e.g., a ground pattern) having various functions.

The first and second redistribution vias 113 and 183 may have a tapered structure determined according to a formation direction. In an embodiment, the first redistribution via 113 may have a width narrowing from an upper surface 110T of the first redistribution structure 110 toward a lower surface 110B of the first redistribution structure 110. In addition, the second redistribution via 183 may also have a width narrowing from an upper surface of the second redistribution structure 180 toward a lower surface of the second redistribution structure 180.

In an embodiment, the third semiconductor chip 250 may be mounted on the second redistribution structure and connected to the second redistribution layer 180. The third semiconductor chip 250 may include a semiconductor substrate 251 and contact pads 254 arranged on an active surface of the semiconductor substrate 251, and the contact pads 254 may be connected to pad regions of the second redistribution layer 185 by third conductive bumps 145C.

In an embodiment, the first semiconductor chip 120 and the second semiconductor chip 130 may be a first logic chip and a second logic chip respectively having different functions. In some example embodiments, the third semiconductor chip 250 may be a memory chip, and the first and second logic chips may be chips configured by splitting processing functions for operating the memory chip, respectively. As described above, when a series of functions is divided into a plurality of chips, it is possible to provide an advantage of improving a yield. For example, the memory chip 250 may be a volatile memory chip and/or a non-volatile memory chip.

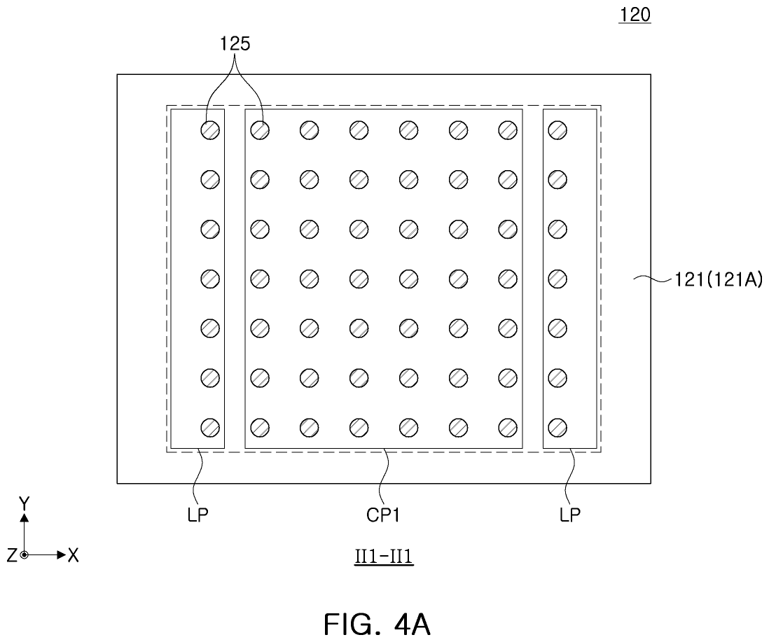

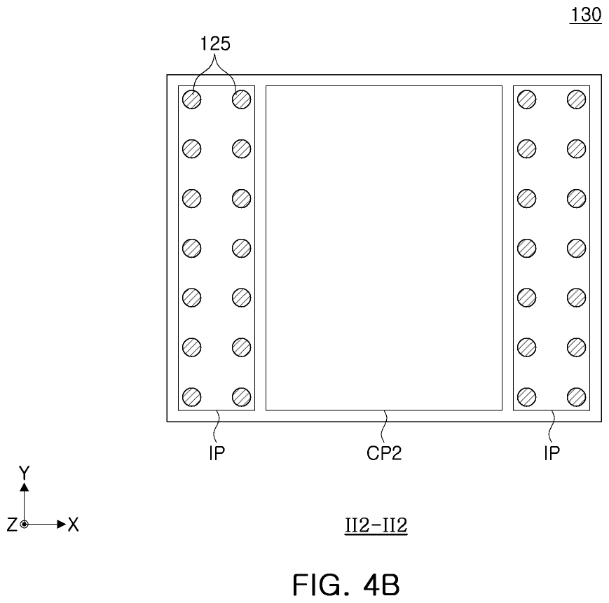

FIGS. 4A and 4B are schematic plan views illustrating a floor plan of each of the first semiconductor chip (first logic chip) and the second semiconductor chip (second logic chip) illustrated in FIG. 3, respectively. FIGS. 4A and 4B may be understood as a plan view when the chip stack CS1 of FIG. 3 is cut at II1-II1 and II2-II2.

Referring to FIG. 4A, the first logic chip 120 includes a first processor core portion CP1 and a logic portion LP, and the first processor core portion CP1 may be disposed in a central region, and the logic portion LP may be arranged on both sides of the first core portion CP1, that is, on opposite sides thereof. However, the disclosure is not limited thereto, and the logic portion LP may be additionally disposed in another corner region, or may be disposed only in a region adjacent to one corner.

Referring to FIG. 4B, the second logic chip 130 may include a second core portion CP2 having a function different from that of the first processor core portion CP1 and a memory interface portion IP. The second processor core portion CP2 may be disposed in a central region, and the memory interface portion IP may be disposed at two sides of the second processor core portion CP2 opposite to each other. For example, the memory interface portion IP may be a double data rate (DDR) interface. The memory interface portion IP transmits data between a memory controller (e.g., the first and second processor core portions CP1 and CP2 and the logic portion LP) and a memory chip 250 through several data lines.

In an arrangement according to an embodiment, the second logic chip 130 may be interconnected to transmit a signal to the first logic chip 120, and may be connected to the memory chip 250 to transmit a signal through the second redistribution layer 185. By disposing the memory interface portion IP on the second logic chip 130 in place of the first logic chip 120, the memory chip 250 and an interface path P2 (see, e.g., FIG. 1) may be shortened.

In particular, when the memory interface portion IP is included in the first logic chip 120 and does not include a second through-electrode 135 of the second logic chip 130, since the first logic chip 120 has to communicate with the first and second redistribution layers 115 and 185 through some conductive posts 155P, there is a problem in that additional conductive posts are required, which may increase a package size.

In contrast thereto, according to an embodiment, by not only disposing the memory interface portion IP on the second logic chip 130 and communicating with the memory chip 250 through the second through-electrode 135 and the second redistribution layer 185 to shorten an interface path P2, but also reducing the number of conductive posts 155P, the package size may be reduced.

Meanwhile, power for the memory chip 250 may be supplied to the memory chip 250 through a path P1 (see, e.g., FIG. 1) connected to the first redistribution layer 115, the conductive posts 155P, and the second redistribution layer 185.

The semiconductor package 300 according to an embodiment may further include an under bump metallurgy (UBM) layer 118 disposed on the lower surface 110B of the first redistribution layer 110 and connected to the first redistribution layer 115, and an electrical connection metal body 119 disposed on the UBM layer 118. The first redistribution structure 110 may be physically and/or electrically connected to an external device (e.g., a main board) through the UBM layer 118 and the electrical connection metal body 119. Each of the electrical connection metal bodies 119 may include a solder such as a low-melting point metal, for example, tin (Sn)-aluminum (Al)-copper (Cu). In some example embodiments, the electrical connection metal body 119 may include a conductive pillar in place of the UBM layer 118.

FIG. 5 is a side cross-sectional view of a semiconductor package according to an example embodiment of the disclosure, and FIG. 6 is a side cross-sectional view illustrating chip stacks (first and second semiconductor chips) introduced into the semiconductor package illustrated in FIG. 5.

Referring to FIGS. 5 and 6, it can be understood that a semiconductor package 300A according to an embodiment is similar to the semiconductor package 300 illustrated in FIGS. 1 to 4B, except that a chip stack CS2 of the first and second semiconductor chips 120 and 130 has a direct-bonding structure. The description of the components of the present embodiment may refer to descriptions of the same or similar components of the semiconductor package 300 illustrated in FIGS. 1 to 4B unless otherwise specifically stated.

The chip stack CS2 employed in an embodiment has a structure in which the first semiconductor chip 120 and the second semiconductor chip 130 are directly bonded. Specifically, first upper pads 127 of the first semiconductor chip 120 and second lower pads 134 of the second semiconductor chip 130 may be directly bonded to form a metal-to-metal junction, a first back side insulating layer 126 (in particular, a second dielectric film 126b) of the first semiconductor chip 120 and a dielectric layer 133 of the second semiconductor chip 130 may be directly bonded to form a dielectric-dielectric junction. Such a bonding is also referred to as “hybrid bonding.”

Referring to FIG. 6, the back side insulating layer 126 of the first semiconductor chip 120 includes a first dielectric film 126a separating the first semiconductor substrate 121 from the first upper pads 127, and a second dielectric film 126b in which the upper pads 127 are buried. An upper surface 126T of the second dielectric layer 126b is substantially flat and coplanar with the upper surface 127T of the upper pads 127.

As described above, a circuit layer 132 of the second semiconductor chip 130 includes an insulating layer and an interconnection pattern WP constituting an interconnection circuit connected to an active region in the insulating layer. In addition, the circuit layer 132 of the second semiconductor chip 130 includes an additional dielectric layer 133, and the second lower pads 134 are buried in the dielectric layer 133. A lower surface 133B of the dielectric layer 133 is substantially flat and coplanar with a lower surface 134B of the second lower pads 134.

The first semiconductor chip 120 and the second semiconductor chip 130 may be bonded to each other by bonding of the dielectric layer 133 to the second dielectric film 126b and by bonding of first upper pads 127 to second lower pads 134. Since a surface to be bonded has a sufficiently clean and planarized surface, voids are not generated at a bonding interface and strong bonding can be ensured. Specifically, the first upper pads 127 and the second lower pads 134 may include the same metal, for example, copper (Cu). The directly bonded first upper pads 127 and the second lower pads 134 may be coupled by copper interdiffusion through an annealing process at a high temperature. The metal constituting the first upper pads 127 and the second lower pads 134 is not limited to copper, but may include another metal material (e.g., Au) that may be similarly coupled to each other. The bonding between the pads may promote electrical connection together with strong bonding.

The metal constituting the first upper pads 127 and the second lower pads 134 is not limited to copper, but may include another metal material (e.g., Au) that may be similarly coupled to each other. The bonding between the pads may promote electrical connection together with a strong bonding. In some example embodiments, the first dielectric film 126b and the dielectric layer 126 may include different insulating materials or additionally include insulating films formed of different materials. For example, these other materials may include other insulating films such as SiCN, SiON or SiCO.

Unlike the previous chip stack CS1, a chip stack CS2 employed in an embodiment shown, e.g., in FIGS. 5 and 6 may be performed by a method of bonding a second wafer in which a plurality of second semiconductor chips 130 are implemented on a first wafer in which a plurality of first semiconductor chips 120 are implemented and then separating the bonded structure into single units. As a result, in an embodiment, the first and second semiconductor chips 120 and 130 may be formed to have the same area.

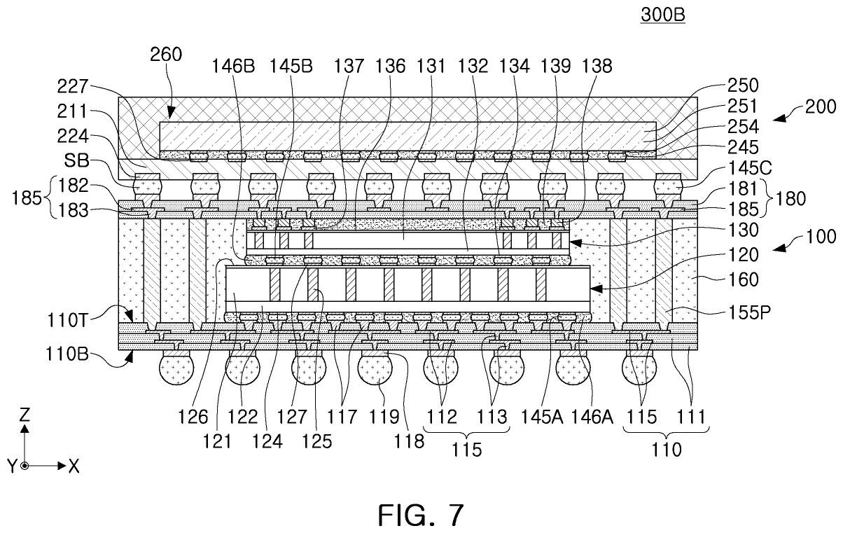

FIG. 7 is a side cross-sectional view of a semiconductor package according to an example embodiment of the disclosure.

Referring to FIG. 7, it can be understood that a semiconductor package 300B according to an embodiment is similar to the semiconductor package 300 illustrated in FIGS. 1 to 4B, except that an additional upper semiconductor package 200 is mounted on the second redistribution structure 180 in place of mounting the third semiconductor chip (“250” in FIG. 1) thereon. The description of the components of the present embodiment may refer to descriptions of the same or similar components of the semiconductor package 300 illustrated in FIGS. 1 to 4B unless otherwise specifically stated.

The semiconductor package 300B according to an embodiment has a package-on-package (POP) structure. The lower semiconductor package 100 may be a package including a chip stack of first and second semiconductor chips 120 and 130, similar to the structure described with reference to FIG. 1, and the upper semiconductor package 200 may be a package including a third semiconductor chip 250.

Specifically, the upper semiconductor package 200 may include a circuit board 211 having a lower pad 224 and an upper pad 227, and a molded portion 260 disposed on the circuit board 211 and surrounding the third semiconductor chip 250. The contact pads 254 of the third semiconductor chip 250 may be respectively connected to the upper pads 227 of the circuit board 211 by conductive bumps 245. Solder balls SB respectively disposed on the lower pads of the circuit board 211 may be connected to the second redistribution layer 185 of the lower semiconductor package 100. In this connection, the third semiconductor chip 250 may be connected to the second semiconductor chip 130 by way of the second redistribution layer 185 and the circuit board 211. Specifically, the second semiconductor chip 130 may not only be interconnected to transmit signals with the first semiconductor chip 120, but also connected to transmit signals with the third semiconductor chip 250 by way of the second redistribution layer 185 and the circuit board 211, and may shorten an interface path of the second semiconductor chip 130 and the third semiconductor chip 250 due to the introduction of the second through-electrode 135 and the second redistribution layer 185.

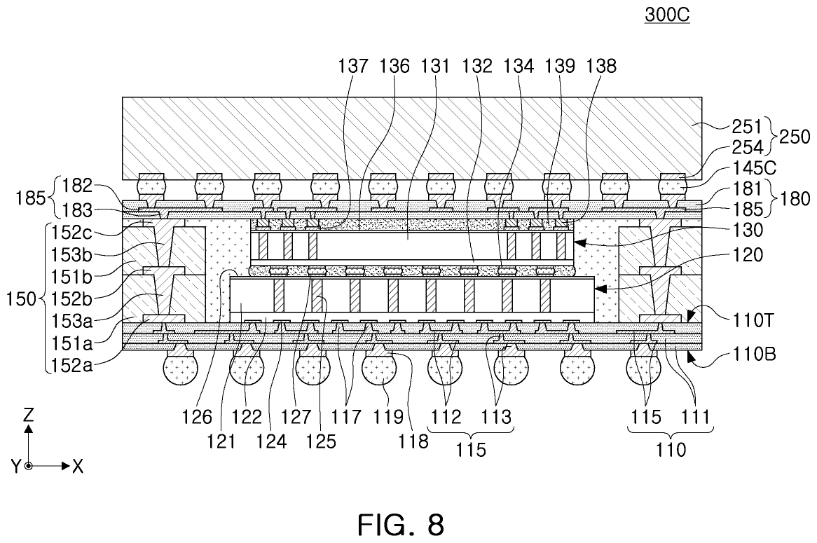

FIG. 8 is a side cross-sectional view of a semiconductor package according to an example embodiment of the disclosure.

Referring to FIG. 8, it can be understood that a semiconductor package 300C according to an embodiment is similar to the semiconductor package 300 illustrated in FIGS. 1 to 4B, except that a frame 150 having an interconnection structure in place of a conductive post (“155P” in FIG. 1) as a vertical connection conductor connecting the first and second redistribution layers 115 and 185 is introduced and a method of forming the first redistribution structure 110 is different. The description of the components of the present embodiment may refer to descriptions of the same or similar components of the semiconductor package 300 illustrated in FIGS. 1 to 4B unless otherwise specifically stated.

The semiconductor package 300C according to an embodiment includes a frame 150 disposed on the first redistribution structure 110 and having a cavity 150C. The first semiconductor chip 120 and the second semiconductor chip 130 may be disposed in the cavity 150C of the frame 150.

The frame 150 may further improve rigidity of the semiconductor package 100 according to a specific material, and may serve to secure uniform thickness of the molding unit 160. The frame 150 may have an interconnection structure connecting an upper surface and a lower surface thereof.

The frame 150 may be disposed on the first redistribution structure 140, and a lower surface of the interconnection structure, that is, the first interconnection layer 152a may be connected to the first redistribution layer 115. The frame 150 may be electrically connected to the first and second semiconductor chips 120 and 130 through the first redistribution layer 115. In addition, it may be connected to an upper surface of the interconnection structure 115 exposed from the molding unit 160, that is, the third interconnection layer 152c may be connected to the second redistribution layer 185. Accordingly, the interconnection structure may be provided as a vertical connection conductor connecting the first redistribution layer 115 to the second redistribution layer 185.

The frame 150 employed in this embodiment may include a first insulating layer 151a, a first interconnection layer 152a in contact with the first redistribution layer 115 and buried in the first insulating layer 151a, a second interconnection layer 152b disposed on an opposite side of a side in which the first interconnection layer 152a of the first insulating layer 151a is buried, a second insulating layer 151b disposed on the first insulating layer 151a and covering the second interconnection layer 152b, and a third interconnection layer 152c disposed on the second insulating layer 151b. The first to third interconnection layers 152a, 152b, and 152c may be electrically connected to each other through first to second interconnection vias 153a and 153b penetrating through the first and second insulating layers 151a and 151b, respectively.

In an embodiment, when the first interconnection layer 152a is buried in the first insulating layer 151a, a step portion generated by a thickness of the first interconnection layer 152a can be minimized, so that an insulating distance of the first redistribution structure 110 may be implemented more uniformly. In the first interconnection layer 152a, the first insulating layer 151a may be recessed internally, so that a lower surface of the first insulating layer 151a may have a step from the lower surface of the first interconnection layer 152a. In this case, it is possible to prevent a material of the molded portion 160 from bleeding and contaminating the first interconnection layer 152a in a process of forming the molded portion 160. The frame 150 may be manufactured to have a sufficient thickness by a substrate process, or the like, whereas the redistribution structure 110 may be manufactured to have a thin thickness by a semiconductor process or the like, and thus a thickness of each of the first to third interconnection layers 152a, 152b, and 152c of the frame 150 may be greater than a thickness of each of the first redistribution layers 115 of the first redistribution structure 110. For example, the first and second insulating layers 151a and 151b may be formed of a thermosetting resin such as an epoxy resin, a thermoplastic resin such as polyimide, or a resin in which these resins are mixed with an inorganic filler, or a resin impregnated with a core material such as glass fiber (Glass Fiber, Glass Cloth, Glass Fabric) together with an inorganic filler, for example, prepreg, ABF, FR-4, BT, or the like may be used. For example, the first to third interconnection layers 152a, 152b, and 152c may include a conductive material such as copper (Cu), aluminum (Al), silver (Ag), tin (Sn), gold (Au), nickel (Ni), lead (Pb), titanium (Ti), or alloys thereof. The first to third interconnection layers 152a, 152b, and 152c may perform various functions according to the design and design of the corresponding layers. When formed by the same plating process, the first and second interconnection vias 153a and 153b may be integrated with the second and third interconnection layers 152b and 152c, respectively.

Unlike a previous embodiment, after disposing the chip stack CS1 in the cavity 150C of the frame 150 and forming the molded portion 160, the first redistribution structure 110 employed in this embodiment is directly formed on a lower surface of the first semiconductor chip 120 and a lower surface of the frame 150. Accordingly, the first redistribution layer 115 formed first may be formed to be connected to the lower pads 124 of the first semiconductor chip 120 and the first interconnection layer 152a of the interconnection structure of the frame 150, respectively, through the redistribution via 113. As described above, since a formation direction of the first redistribution structure 110 is different from that of the previous embodiment (FIG. 1), the first redistribution via 113 may have a width narrowing from the lower surface 110B of the first redistribution structure 110 toward the upper surface 110T of the first redistribution structure 110. Meanwhile, the second redistribution via 183 may have a width narrowing from the upper surface of the second redistribution structure 180 toward the lower surface of the second redistribution structure 180, similarly to a previous embodiment.

FIG. 9 is a side cross-sectional view of a semiconductor package according to an example embodiment of the disclosure.

Referring to FIG. 9, it can be understood that a semiconductor package 300D according to an embodiment is similar to the semiconductor package 300C illustrated in FIG. 8, except that a frame 150′ and an interconnection structure have different structures. The description of the components of this embodiment may refer to a description of the same or similar components of the semiconductor package 300 shown in FIGS. 1 to 4B and the semiconductor package 300C illustrated in FIG. 8 unless otherwise specified.

The frame 150′ may include a first insulating layer 151a, a first interconnection layer 152a disposed on one surface of the first insulating layer 151a, a second interconnection layer 152b disposed on the other surface of the first insulating layer 151a, a second insulating layer 151b disposed on one surface of the first insulating layer to cover at least a portion of the first interconnection layer 152a, a third interconnection layer disposed on a surface, on an opposite side of a side in which the first interconnection layer 152a of the second insulating layer 151b is buried, a third insulating layer 151c disposed on the other surface of the first insulating layer 151a to cover at least a portion of the second interconnection layer 152b, and a fourth interconnection layer 152d disposed on a surface on an opposite side of a side in which the second interconnection layer 152b of the third insulating layer 151c is buried.

In addition, the frame 150′ may further include a first interconnection via 153a penetrating through the first insulating layer 151a and electrically connecting the first interconnection layer 152a to the second interconnection layer 152b, a second interconnection via 153b penetrating through the second insulating layer 151b and electrically connecting the first interconnection layer 152a to the third interconnection layer 152c, and a third interconnection via 153c penetrating through the third insulating layer 151c and electrically connecting the second interconnection layer 152b to the fourth interconnection layer 152d.

Since the frame 150′ employed in this embodiment has a larger number of interconnection layers 152a, 152b, 152c, and 152d, the first redistribution layer 115 of the first redistribution structure 110 can be further simplified. Similar to the semiconductor package 300C of FIG. 8, since the first redistribution structure 110 employed in this embodiment is directly formed on the lower surface of the first semiconductor chip 120 and the lower surface of the frame 150, the first redistribution via 113 may have a width narrowing from the lower surface 110B of the first redistribution structure 110 toward the upper surface 110T of the first redistribution structure 110.

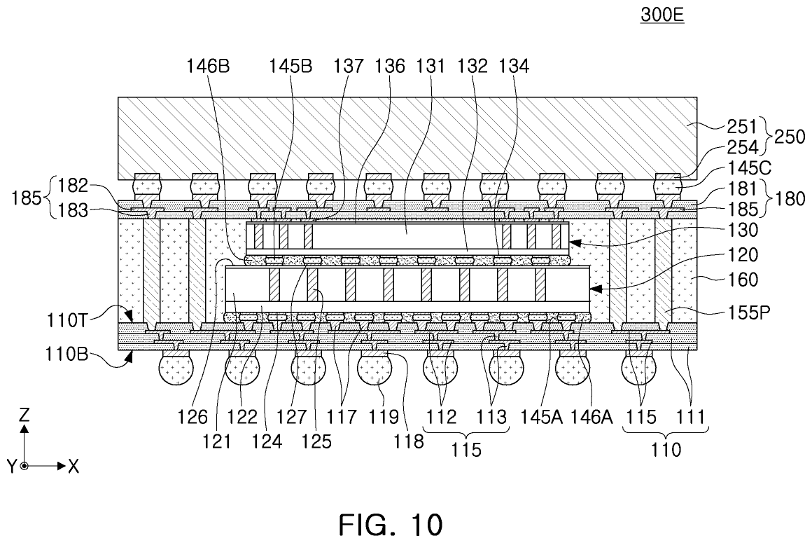

FIG. 10 is a side cross-sectional view of a semiconductor package according to an example embodiment of the disclosure.

Referring to FIG. 10, it can be understood that a semiconductor package 300E according to an embodiment is similar to the semiconductor package 300 illustrated in FIGS. 1 to 4B, except that it is directly connected to the second redistribution layer 185 without a molding layer. The description of the components of the present embodiment may refer to descriptions of the same or similar components of the semiconductor package 300 illustrated in FIGS. 1 to 4B unless otherwise specifically stated.

In this embodiment, second upper pads 137 of the second semiconductor chip 130 may be directly connected to the second redistribution layer 185 of the second redistribution structure 180. As illustrated in FIG. 10, the second upper pads 137 may be exposed from an upper surface of the molded portion 160. A second insulating film 181 may be formed on the molded portion 160, and a hole for opening the second upper pads 137 and a partial region of the conductive post 155P may be formed in the second insulating film 181, and a second redistribution layer 185 may be formed. In some example embodiments, by covering the second upper pads 137 and the conductive post 155P using the molded portion, forming a hole for opening the second pads 137 and a partial region of the conductive post 155P, and forming a second redistribution layer 185 on an upper surface of the molded portion 160, the second redistribution layer 185 and the second upper pads 137 may be directly connected to each other.

As described above, the second upper pads 137 of the second semiconductor chip 130 and the second redistribution layer 185 may be directly connected to each other without using the contact post and the molding layer.

FIGS. 11A to 11E are cross-sectional views for each main process for illustrating a method of manufacturing the semiconductor package illustrated in FIG. 1.

Referring to FIG. 11A, a first redistribution structure 110 is built-up on a support substrate 510, and conductive posts 155P are formed in a corner region of an upper surface 110T of the first redistribution structure 110.

A process of forming the first redistribution structure 110 may include a process of a first insulating film 111 on the support substrate 510 by using a lamination or coating method (e.g., spin coating), a process of forming via-holes in the first insulating film 111, and a process of forming a first redistribution pattern 112 and a redistribution via 113 by electroplating or electroless plating. For example, as a material of the first insulating film 111, a photosensitive insulating material (PID) may be used as described above. In this case, the via-holes may be formed with a finer pitch using a photolithography method.

The conductive posts 155P may be provided as vertical connection conductors connected to the first redistribution layer 115. In an embodiment, the conductive posts 155P may be formed from the exposed region of the first redistribution layer 115 using a plating process. The plating process may be an electroplating process or an electroless plating process. For example, the conductive posts 155P may be formed using a subtractive, additive, semi-additive process (SAP), or a modified semi-additive process (MSAP). The conductive posts 155P may be formed to have a height, greater than a final height in consideration of a subsequent planarization process. In an uppermost redistribution layer, connection pads 117 to be connected to the first semiconductor chip 120 to be mounted may be formed. The connection pads 117 may be arranged to correspond to the first lower pads 124 of the first semiconductor chip 120.

Next, referring to FIG. 11B, a stack of the first and second semiconductor chips 120 and 130 may be disposed on the first redistribution structure 110.

The stack of the first and second semiconductor chips is prefabricated like the chip stack CS1 illustrated in FIG. 3, and in this process, the prefabricated stack may be mounted on the first redistribution structure 110. During a mounting process, lower pads 124 of the first semiconductor chip 120 may be respectively bonded to connection pads 117 by first conductive bumps 145A, respectively. Through such bonding, the first semiconductor chip 120 may be connected to a first redistribution layer 115. In an embodiment, an adhesive film such as a first non-conductive film 146A may be disposed between the first semiconductor chip 120 and the first redistribution structure 110 to be formed to surround the first conductive bumps 145A for more robust and stable bonding. This bonding process may be performed by a thermocompression bonding process.

Next, referring to FIG. 11C, conductive posts and the contact posts are exposed using a planarization process of partially removing a molded portion after forming the molded portion.

A molded portion 160 for sealing a stack of the first and second semiconductor chips 120 and 130 and the conductive posts 155P is formed using an encapsulant. The molded portion 160 may be formed to a thickness sufficient to cover the stack of the first and second semiconductor chips 120 and 130 and the conductive posts 155P. Next, a planarization process such as grinding is performed on a surface of the molded portion 160 until upper surfaces of the conductive posts 155P and the contact bumps 138 are exposed (e.g., PL1 line). The upper surfaces of the conductive posts 155P may be exposed, and upper surfaces of the contact posts 138 may be exposed at the same level as the exposed upper surfaces of the conductive posts 155P. In this process, a molding layer 139 surrounding the contact posts 138 may also be partially removed, and the molding layer 139 may have an upper surface that is flat and coplanar with the upper surfaces of the contact posts 138. In addition, the planarized upper surface of the molded portion 160 may have the same level as the molding layer 139 and the upper surfaces of the contact posts 138 and the upper surfaces of the conductive posts 155P. This leveling, i.e., the planarization process, may provide advantageous conditions for forming a second redistribution structure.

Next, referring to FIG. 11D, a second redistribution structure 180 is formed on the planarized surfaces.

A process of forming the second redistribution structure 180 may be performed similarly to a process of forming the first redistribution structure 110. Specifically, a second insulating film 181 is formed on the planarized surfaces, a via-hole is formed using a photolithography process, a second redistribution layer 185 is formed using a plating process, and by repeatedly performing this process for a desired number of layers, a desired second redistribution structure 180 may be formed.

Next, referring to FIG. 11E, after substrate 510 is removed from the first redistribution structure, the electrical connection metal body 119 may be formed on a UBM layer 118. Next, the semiconductor package 300A illustrated in FIG. 1 may be manufactured by mounting a third semiconductor chip 250 on the second redistribution structure 180 to be connected to the second redistribution layer 185.

In some example embodiments, the contact posts 138 and the molding layer 139 may be omitted from an upper surface of the second semiconductor chip 120. For example, when the molded portion 160 is formed of PID, openings through which the conductive posts 155P and the second upper pads 137 are exposed are formed using a photolithography process, and then a second redistribution layer 185 may be directly formed on a surface of the molded portion 160.

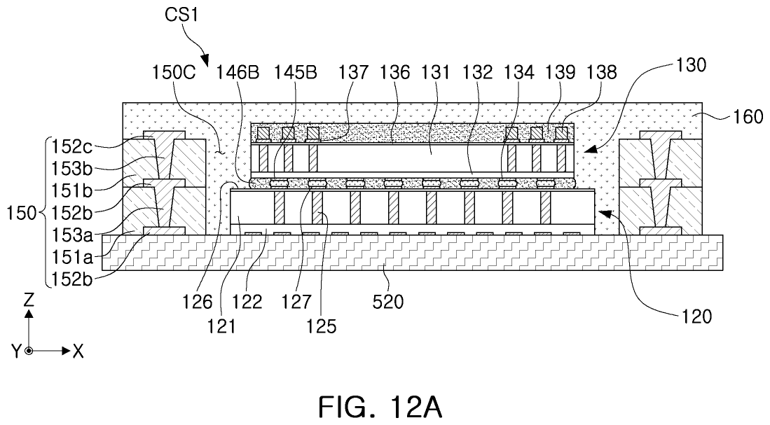

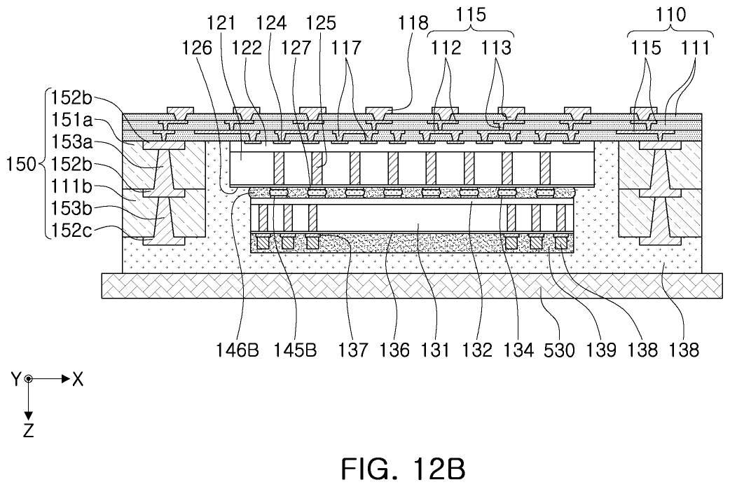

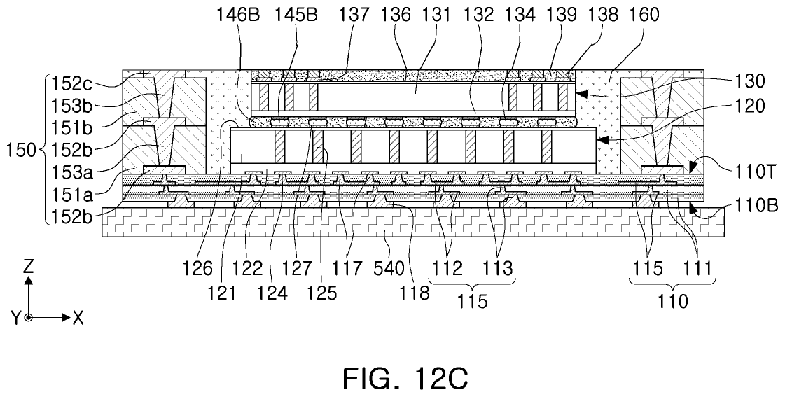

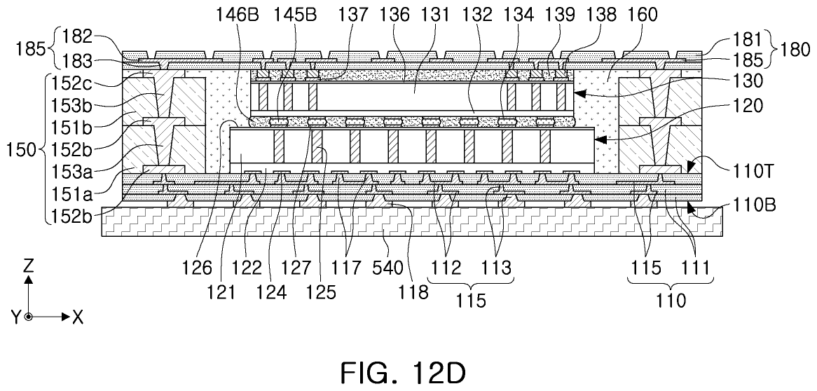

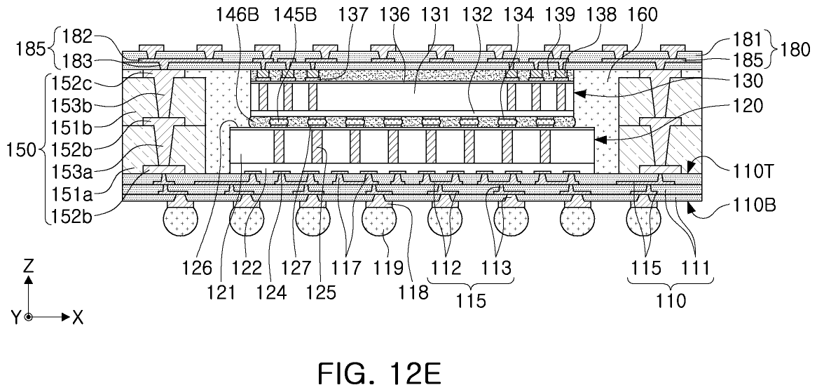

FIGS. 12A to 12E are cross-sectional views for each main process for illustrating a method of manufacturing the semiconductor package illustrated in FIG. 8.

Referring to FIG. 12A, after a frame 150 having a cavity 150C may be disposed on a first carrier film 520, and a stack of first and second semiconductor chips 120 and 130 may be accommodated in the cavity 150C and then a molded portion 160 may be formed.

The frame 150 employed in this embodiment includes an interconnection structure together with first and second insulating layers 151a and 151b as in the previous embodiment (FIG. 8), and the interconnection structure may include first to third interconnection layers 152a, 152b, and 152c and interconnection vias 153a and 153b connecting the same. The first carrier film 520 is attached to a lower side of the first insulating layer 151a. For example, the first carrier film 520 may be an adhesive tape including an epoxy resin.

A stack of the first and second semiconductor chips 120 and 130 may be mounted in the cavity 150C of the frame 150. Such a stack may be a prefabricated chip stack CS1 as illustrated in FIG. 3. Next, a molded portion 160 for sealing the first and second semiconductor chips 120 and 130 may be formed using an encapsulant. The molded portion 160 may cover the first and second semiconductor chips 120 and 130, and may be formed to extend to an upper surface of the frame 150 to cover the third interconnection layer 152c.

Next, referring to FIG. 12B, after attaching a second carrier film 530 to an upper surface of the molded portion 160, and removing the first carrier film 520, a first redistribution structure 110 is formed on the removed surface thereof.

A process of forming the first redistribution structure 110 may include a process of forming a first insulating film 111 using a lamination or coating method (e.g., spin coating), a process of forming via-holes in the first insulating film 111, and a process of forming a first redistribution pattern 112 and a redistribution via 113 by electroplating or electroless plating. For example, the first insulating film 111 may be formed of a photosensitive insulating material (PID) as described above. In this case, the via-holes may be formed with a finer pitch using a photolithography method. Additionally, an underbump metal layer 118 connected to the first redistribution layer 115 may be formed.

Next, referring to FIG. 12C, after attaching a third carrier film 540 to the first redistribution structure 110, the second carrier film 530 may be removed from the molded portion 160, and it may be planarized so that an upper surface of the interconnection structure 155 and the contact bump 13 are exposed.

A planarization process such as grinding is performed on a surface of the molded portion 160 from which the second carrier film 530 has been removed until the upper surface of the interconnection structure 155 and the contact bump 138 are exposed. A third interconnection layer 152c of the interconnection structure 155 may be exposed, and upper surfaces of the contact posts 138 may be exposed at the same level as an upper surface of the third interconnection layer 152c of the interconnection structure 155. In this process, a molding layer 139 surrounding the contact posts 138 may also be partially removed, and the remaining molding layer 139 may have an upper surface that is flat and coplanar with the upper surface of the contact posts 138. The remaining upper surface of the molded portion 160 may also have the same level as the molding layer 139 and the third interconnection layer 152c.

Next, as illustrated in FIG. 12D, a second redistribution structure 180 is formed on planarized surfaces.

A process of forming the second redistribution structure 180 may be performed similarly to the process of forming the first redistribution structure 110. Specifically, a second insulating film 181 may be formed on the planarized surfaces, via-holes may be formed using a photolithography process, a second redistribution layer 185 may be formed using a plating process, and by repeatedly performing the process to a desired number of layers, a desired second redistribution structure 180 may be formed.

Next, as illustrated in FIG. 12E, after a third carrier film 540 is removed from the first redistribution structure, an electrical connection metal body 119 may be formed on a UBM layer 118. Subsequently, the third semiconductor chip 250 may be mounted on the second redistribution structure 180 to be connected to the second redistribution layer 185.

In some example embodiments, the contact posts 138 and the molding layer 139 may be omitted from the upper surface of the second semiconductor chip 120. For example, in the case of forming the molded portion 160 by PID, after forming openings through which a partial region of the third interconnection layer 152c and the second upper pads 137 are exposed using a photolithography process, the second redistribution layer 185 may be directly formed on a surface of the molded portion 160.

As set forth above, in a semiconductor package according to the present embodiment, some functional blocks (e.g., memory interface) of a first semiconductor chip (e.g., first logic chip) may be configured to be included in a second semiconductor chip (e.g., second logic chip) stacked on the first semiconductor chip, and to connect the second semiconductor chip to a third semiconductor chip (e.g., memory chip) disposed on the semiconductor package through a through-electrode (e.g., TSV), thereby shortening an interface path, as well as reducing the number of vertical connection conductors (e.g., conductive posts) and thus the space may be reduced.

Herein, a lower side, a lower portion, a lower surface, and the like, are used to refer to a direction toward a mounting surface of the fan-out semiconductor package in relation to cross sections of the drawings, while an upper side, an upper portion, an upper surface, and the like, are used to refer to an opposite direction to the direction. However, these directions are defined for convenience of explanation, and the claims are not particularly limited by the directions defined as described above.

The meaning of a “connection” of a component to another component in the description includes an indirect connection through an adhesive layer as well as a direct connection between two components. In addition, “electrically connected” conceptually includes a physical connection and a physical disconnection. It can be understood that when an element is referred to with terms such as “first” and “second,” the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The term “an example embodiment” used herein does not refer to the same example embodiment, and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

Terms used herein are used only in order to describe an example embodiment rather than limiting the present disclosure. In this case, singular forms include plural forms unless interpreted otherwise in context.

While example embodiments have been shown and described above, it will be apparent to those skilled in the art that modifications and variations could be made without departing from the scope of the disclosure as defined by the appended claims.

What is claimed is:

1. A semiconductor package, comprising:
a first redistribution structure comprising a first redistribution layer;
a first semiconductor chip on the first redistribution structure, the first semiconductor chip comprising first lower pads, first upper pads, and first through-electrodes electrically connecting the first lower pads to the first upper pads, wherein the first lower pads are electrically connected to the first redistribution layer;
a second semiconductor chip on the first semiconductor chip, the second semiconductor chip comprising second lower pads, second upper pads, and second through-electrodes electrically connecting the second lower pads to the second upper pads, wherein the second lower pads are electrically connected to the first upper pads;
a vertical connection conductor around the first semiconductor chip and the second semiconductor chip on the first redistribution structure, wherein the vertical connection conductor is electrically connected to the first redistribution layer;
a molded portion on the first redistribution structure, wherein the molded portion surrounds the first semiconductor chip and the second semiconductor chip;
a second redistribution structure on the second semiconductor chip and the vertical connection conductor, the second redistribution structure comprising a second redistribution layer connected to the second upper pads and to the vertical connection conductor; and
a third semiconductor chip on the second redistribution structure, the third semiconductor chip comprising contact pads electrically connected to the second redistribution layer.

2. The semiconductor package of claim 1, wherein the first semiconductor chip comprises a first logic chip and the second semiconductor chip comprises a second logic chip having a function different from a function of the first logic chip, and
wherein the third semiconductor chip comprises a memory chip.

3. The semiconductor package of claim 2, wherein the first logic chip comprises a first processor core portion and a logic portion, and the second logic chip comprises a second processor core portion and a memory interface portion.

4. The semiconductor package of claim 3, wherein the memory chip is connected to the memory interface portion of the second logic chip by way of the second through-electrode and the second redistribution layer, and
wherein power is supplied to the memory chip by way of the first redistribution layer, the vertical connection conductor, and the second redistribution layer.

5. The semiconductor package of claim 1, wherein the first semiconductor chip is electrically connected to the first redistribution layer by first conductive bumps.

6. The semiconductor package of claim 5, further comprising:
a first non-conductive film surrounding the first conductive bumps between the first semiconductor chip and the first redistribution structure.

7. The semiconductor package of claim 5, wherein the vertical connection conductor comprises a plurality of conductive posts on the first redistribution structure, wherein the plurality of conductive posts are connected to the first redistribution layer, and
wherein the molded portion surrounds the plurality of conductive posts.

8. The semiconductor package of claim 1, further comprising:
a frame on the first redistribution structure, the frame having a cavity in which the first semiconductor chip and the second semiconductor chip are located,
wherein the vertical connection conductor penetrates through an upper surface of the frame and a lower surface of the frame, and is provided as an interconnection structure for electrically connecting the first redistribution layer to the second redistribution layer.

9. The semiconductor package of claim 1, wherein the first upper pads of the first semiconductor chip are connected to respective ones of the second lower pads of the second semiconductor chip by second conductive bumps.

10. The semiconductor package of claim 9, further comprising:
a second non-conductive film surrounding the second conductive bumps between the first semiconductor chip and the second semiconductor chip.

11. The semiconductor package of claim 9, wherein the first semiconductor chip has an area, greater than an area of the second semiconductor chip.

12. The semiconductor package of claim 1, wherein the first semiconductor chip comprises a first dielectric layer on an upper surface of the first semiconductor chip, and each of the first upper pads has an upper surface, which is substantially coplanar with an upper surface of the first dielectric layer,
wherein the second semiconductor chip comprises a second dielectric layer on a lower surface of the second semiconductor chip, and each of the second lower pads has a lower surface which is substantially coplanar with a lower surface of the second dielectric layer,
wherein the upper surface of the first dielectric layer is directly bonded to the lower surface of the second dielectric layer, and
wherein the upper surface of each of the first upper pads is directly bonded to the lower surface of a corresponding one of the second lower pads.

13. The semiconductor package of claim 12, wherein the first semiconductor chip has an area equal to an area of the second semiconductor chip.

14. The semiconductor package of claim 1, wherein the second semiconductor chip comprises contact posts respectively disposed on the second upper pads, wherein each of the contact posts has a predetermined height,
wherein the second semiconductor chip further comprises a molding layer on an upper surface of the second semiconductor chip, and
wherein the molding layer has an upper surface which is substantially coplanar with an upper surface of the contact posts.

15. The semiconductor package of claim 1, wherein the second lower pads are in a central region of a lower surface of the second semiconductor chip, and the second upper pads are in a region adjacent to a corner of the lower surface of the second semiconductor chip.

16. A semiconductor package, comprising:
a first redistribution structure comprising a first redistribution layer;
a first logic chip on the first redistribution structure, the first logic chip comprising first lower pads, first upper pads, and first through-electrodes electrically connecting the first lower pads to the first upper pads, wherein the first lower pads are electrically connected to the first redistribution layer, and wherein the first logic chip comprises a first processor core portion and a logic portion;
a second logic chip on the first logic chip, the second logic chip comprising second lower pads, second upper pads, and second through-electrodes electrically connecting the second lower pads to the second upper pads, wherein the second lower pads are electrically connected to the first upper pads, and wherein the second logic chip comprises a second processor core portion and a memory interface portion;
conductive posts around the first logic chip and the second logic chip on the first redistribution structure, wherein the conductive posts are electrically connected to the first redistribution layer;
a molded portion on the first redistribution structure, wherein the molded portion surrounds the first logic chip, the second logic chip, and the conductive posts;
a second redistribution structure on an upper surface of the second logic chip and an upper surface of the molded portion, the second redistribution structure comprising a second redistribution layer connected to the second upper pads and to the conductive posts; and
a memory chip on the second redistribution structure, the memory chip comprising contact pads electrically connected to the second redistribution layer.

17. The semiconductor package of claim 16, wherein the memory chip is connected to a memory interface of the second logic chip by way of the second through-electrode and the second redistribution layer.

18. The semiconductor package of claim 16, wherein power is supplied to the memory chip by way of the first redistribution layer, the conductive posts, and the second redistribution layer.

19. A semiconductor package, comprising:
a first redistribution structure comprising a first redistribution layer;
a frame on the first redistribution structure, the frame comprising an interconnection structure connected to the first redistribution layer, wherein the frame includes a cavity passing through an upper surface of the frame and a lower surface of the frame;
a first logic chip on the first redistribution structure within the cavity of the frame, the first logic chip comprising first lower pads, first upper pads, and first through-electrodes electrically connecting the first lower pads to the first upper pads, wherein the first lower pads are electrically connected to the first redistribution layer, and wherein the first logic chip comprises a first processor core portion and a logic portion;
a second logic chip on the first logic chip within the cavity, the second logic chip comprising second lower pads, second upper pads, and second through-electrodes electrically connecting the second lower pads to the second upper pads, wherein the second lower pads are electrically connected to the first upper pads, and wherein the second logic chip comprises a second processor core portion and a memory interface portion;
a molded portion surrounding the first logic chip and the second logic chip within the cavity;
a second redistribution structure on an upper surface of the second logic chip and an upper surface of the frame, the second redistribution structure comprising a second redistribution layer connected to the second upper pads and to the interconnection structure; and
a memory chip on the second redistribution structure, the memory chip comprising contact pads electrically connected to the second redistribution layer.

20. The semiconductor package of claim 19, wherein the memory chip is connected to a memory interface of the second logic chip by way of the second through-electrode and the second redistribution layer, and
wherein power is supplied to the memory chip by way of the first redistribution layer, the interconnection structure, and the second redistribution layer.
